(19) United States
(12) Patent Application Publication
(10) Pub. No.: US 2025/0221172 A1
(43) Pub. Date: Jul. 3, 2025

(54) DISPLAY PANEL AND DISPLAY DEVICE

(71) Applicant: LG Display Co., Ltd., Seoul (KR)

(72) Inventors: Yongmin KIM, Paju-si (KR); Yooji HWANG, Paju-si (KR); JungSun BAEK, Paju-si (KR)

(73) Assignee: LG Display Co., Ltd., Seoul (KR)

(21) Appl. No.: 18/967,191

(22) Filed: Dec. 3, 2024

(30) Foreign Application Priority Data
Dec. 29, 2023 (KR) 10-2023-0197853

(51) Int. Cl. H10K 59/122

(52) U.S. Cl. CPC H10K 59/122

(57) ABSTRACT

A display device can include a disconnection inducing layer disposed on a first insulating layer and having a first open area exposing a portion of an upper surface of the first insulating layer, and a second insulating layer disposed on a substrate. The second insulating layer includes at least one opened portion in at least one subpixel and a second open area in an area overlapping with the first open area. A portion of the second insulating layer overlaps with a portion of the first open area of the disconnection inducing layer. As such, the display device is capable of preventing leakage current from flowing between subpixels by causing an organic layer to be disconnected by the first and second open areas formed in one or more non-light emitting areas between the subpixels.

### CROSS-REFERENCE TO RELATED APPLICATION

This application claims priority to Republic of Korea Patent Application No. 10-2023-0197853, filed on Dec. 29, 2023 in the Korean Intellectual Property Office, the entire contents of which is hereby expressly incorporated by reference for all purposes as if fully set forth herein into the present application.

### BACKGROUND

### Field

The present disclosure relates to electronic devices with displays, and more specifically, to a display panel and a display device.

### Discussion of the Related Art

Displays capable of displaying information and images on a screen are widely used in a variety of electronic device or systems, and are becoming increasingly important as a core technology in today's society for presenting various information to users. To meet various needs, various types of displays, such as liquid crystal displays (LCD), organic light emitting displays (OLED), micro light emitting displays (micro LED), mini light emitting displays (mini LED), quantum dot light emitting displays (QLED), and the like have been developed and widely used.

While display devices are needed to present excellent display quality, there can occur a situation where as a common layer among layers (e.g., one or more organic layers) included in a light emitting element has a low resistance and undesired current can be generated between the subpixels. Such undesired current can cause a subpixel, which is not required to emit light, to emit light, which in turn can cause degradation of display quality.

### SUMMARY OF THE DISCLOSURE

To address this and other issues, one or more aspects of the present disclosure can provide a display panel and a display device that are capable of preventing leakage current from flowing between subpixels.

One or more aspects of the present disclosure can provide a display panel and a display device that have a structure where one subpixel includes a plurality of light emitting areas for emitting light of a same color, and thereby, are capable of being driven with low power through high luminance characteristics.

According to one or more example embodiments of the present disclosure, a display panel can include a substrate on which a plurality of subpixels are disposed, a first insulating layer disposed on the substrate, a disconnection inducing layer disposed on the first insulating layer and including a first open area exposing a portion of the upper surface of the first insulating layer, a second insulating layer disposed on the substrate and including at least one opened portion in at least one subpixel among the plurality of subpixels, a first electrode disposed on the second insulating layer and overlapping with the at least one opened portion, a bank disposed on a portion of the upper surface of the first electrode and the second insulating layer, and including a respective opening in each of the plurality of subpixels, an organic layer disposed on the first electrode, and a second electrode disposed on the organic layer. The second insulating layer can include a second open area in an area overlapping with the first open area, and a portion of the second insulating layer can overlap with a portion of the first open area of the disconnection inducing layer.

According to one or more example embodiments of the present disclosure, a display device can include a substrate on which a plurality of subpixels are disposed, a first insulating layer disposed on the substrate, a disconnection inducing layer disposed on the first insulating layer and including a first open area exposing a portion of the upper surface of the first insulating layer, and a second insulating layer disposed on the substrate and including at least one opened portion in at least one subpixel among the plurality of subpixels. The second insulating layer can include a second open area in an area overlapping with the first open area, and a portion of the second insulating layer can overlap with a portion of the first open area of the disconnection inducing layer.

According to one or more example embodiments of the present disclosure, a display device can include a substrate on which a plurality of subpixels are disposed, and first, second, and third resistance areas disposed on the substrate. The first resistance area can be configured to surround the second resistance area and the third resistance area, the second resistance area can be configured to surround each of the plurality of subpixels, and the third resistance area can be disposed between the plurality of subpixels. A resistance value of the third resistance area can be greater than a resistance value of the first resistance area and a resistance value of the second resistance area.

According to one or more aspects of the present disclosure, a display panel and a display device can have a structure where first and second open areas are formed in a non-light emitting area between subpixels, and are capable of preventing leakage current from flowing between subpixels by causing an organic layer to be disconnected.

According to one or more aspects of the present disclosure, a display panel and a display device can have a structure where one subpixel includes a plurality of light emitting areas and a plurality of non-light emitting areas, and thereby, is capable of being driven with low power through excellent emission efficiency.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 schematically illustrates a system configuration of an example display device according to aspects of the present disclosure;

FIG. 2 is a plan view of an example portion of an active area of the display device according to aspects of the present disclosure;

FIG. 3 is an example cross-sectional view taken along line A-B of FIG. 2;

FIG. 4 schematically illustrates an example portion of the active area of the display device according to aspects of the present disclosure;

FIGS. 5 to 9 schematically illustrate an example method of manufacturing the display device according to aspects of the present disclosure;

FIGS. 10 to 13 illustrate an example structure to which the display device is applied according to aspects of the present disclosure; and

FIG. 14 is a cross-sectional view taken along line C-D of FIG. 10.

### DETAILED DESCRIPTION OF THE EMBODIMENTS

Reference will now be made in detail to embodiments of the present disclosure, examples of which can be illustrated in the accompanying drawings. In the following description, the structures, embodiments, implementations, methods and operations described herein are not limited to the specific example or examples set forth herein and can be changed as is known in the art, unless otherwise specified. Like reference numerals designate like elements throughout, unless otherwise specified. Names of the respective elements used in the following explanations are selected only for convenience of writing the specification and can thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another and may not define order or sequence. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes and the like are mentioned, it should be considered that numerical values for an elements or features, or corresponding information (e.g., level, range, and the like) include a tolerance or error range that can be caused by various factors (e.g., process factors, internal or external impact, noise, and the like) even when a relevant description is not specified. Further, the term “can” fully encompasses all the meanings of the term “may”.

In the following description, various example aspects of the present disclosure are described in detail with reference to the accompanying drawings. With respect to reference numerals to elements of each of the drawings, the same elements can be illustrated in other drawings, and like reference numerals can refer to like elements unless stated otherwise. The same or similar elements can be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, aspects of the present disclosure are not limited to a scale, dimension, size, and thickness illustrated in the drawings.

Further, all the components of each system and each device according to all aspects and embodiments of the present disclosure are operatively coupled and configured.

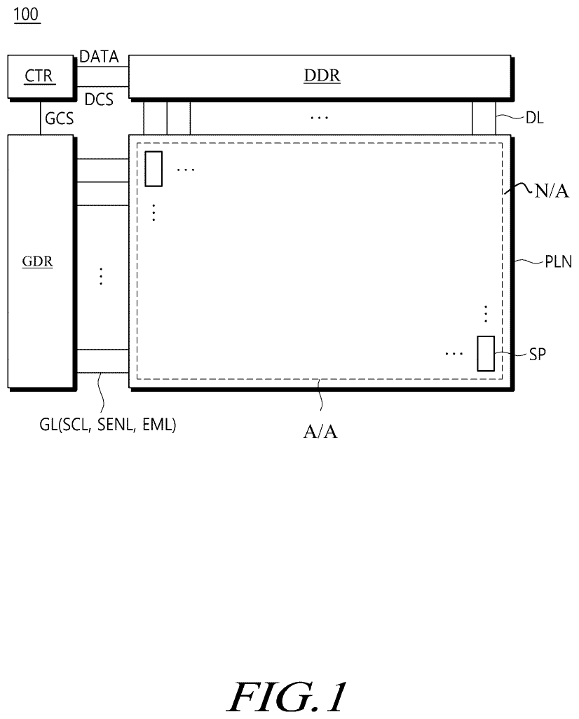

FIG. 1 schematically illustrates a system configuration of an example display device according to aspects of the present disclosure.

Referring to FIG. 1, in one or more aspects, a display device 100 can include an organic light emitting display device, a lighting device, a light emitting device, an inorganic light emitting display device, and the like. Hereinafter, for convenience of description, discussions for the display device 100 are provided based on an example where the display device 100 is implemented as an organic light emitting display device 100. However, it should be understood that as long as at least one transistor is included, aspects, examples, or embodiments described herein can be applicable to various display devices, such as lighting devices, light emitting devices, inorganic light emitting display devices, and the like, as well as the organic light emitting display device 100.

In one or more aspects, the organic light emitting display device 100 can include a display panel PLN configured to display an image or output light, and one or more driving circuits for driving the display panel PLN.

In one or more aspects, the organic light emitting display device 100 can be configured with a bottom emission structure in which light emitted from light emitting elements is directed toward a substrate on which the light emitting elements are disposed, but aspects of the present disclosure are not limited thereto. In one or more aspects, the organic light emitting display device 100 can be configured with a top emission structure in which light emitted from light emitting elements is directed toward a surface opposite to the substrate on which the light emitting elements are disposed, or be configured with a dual emission structure in which light emitted from light emitting elements is directed toward both the substrate and the surface opposite to the substrate.

A plurality of data lines DL and a plurality of gate lines GL can be disposed in the display panel PLN. A plurality of subpixels SP defined by the plurality of data lines DL and the plurality of gate lines GL can be disposed in a matrix in the display panel PLN.

The plurality of data lines DL and the plurality of gate lines GL can be configured to intersect each other in the display panel PLN. For example, the plurality of gate lines GL can be arranged in rows or columns, and the plurality of data lines DL can be arranged in columns or rows. Hereinafter, for convenience of description, discussions are provided based on an example where the plurality of gate lines GL are arranged in rows, and the plurality of data lines DL are arranged in columns.

In addition to the plurality of data lines DL and the plurality of gate lines GL, one or more other types of signal lines can be disposed in the display panel PLN. Different types of signal lines can be disposed in the display panel PLN depending on a subpixel structure and the like. One or more driving power lines, one or more reference power lines, and/or one or more common power lines can be further disposed in the display panel PLN.

The number or types of signal lines disposed in the display panel PLN can vary depending on a subpixel structure and the like. In one or more aspects, at least one of signal lines can include an electrode to which a signal is applied. For example, a part of the at least one signal line can serve as an electrode to which a signal is applied.

The display panel PLN can include an active area A/A (or display area) for allowing images to be displayed, and a non-active area N/A (or non-display area) in which images are not displayed. For example, the non-active area N/A can be located outside of the active area A/A. The non-active area N/A can be referred to as a non-display area, a bezel area, or a bezel. The non-active area N/A can surround the active area A/A entirely or only in part(s).

A plurality of subpixels SP for image display can be disposed in the active area A/A.

A pad area including at least one pad to which a data driver DDR and the like is electrically connected can be located in the non-active area N/A. A plurality of data link lines for connecting a plurality of data lines to pads in the pad area can be disposed in the non-active area N/A. In one or more aspects, the plurality of data link lines can be parts of the plurality of data lines DL extending from the active area A/A to the non-active area N/A, or be separate patterns or line segments electrically connected to the plurality of data lines DL.

In one or more aspects, gate driving related lines can be disposed in the non-active area N/A to deliver at least one type or level of voltage (signal) needed for gate driving to a gate driver GDR through at least one pad to which the data driver DDR and the like is electrically connected. For example, the gate driving related lines can include clock lines for delivering clock signals, gate power lines for delivering gate voltages (VGH and VGL), and gate driving control signal lines for delivering various types of control signals needed for generating scan signals. While at least portions of gate lines GL can be disposed in the active area A/A, the gate driving related lines can be disposed in the non-active area N/A.

The display device 100 can include, as driving circuits for driving the display panel PLN, the data driver DDR for driving a plurality of data lines DL, a gate driver GDR for driving a plurality of gate lines GL, and a controller CTR for controlling the data driver DDR and the gate driver GDR.

The data driver DDR can drive the plurality of data lines DL by supplying data voltages to the plurality of data lines DL.

The gate driver GDR can drive the plurality of gate lines GL by supplying scan signals to the plurality of gate lines GL. As shown in FIG. 1, the plurality of gate lines GL can include a plurality of scan lines SCL, a plurality of sense lines SENL, and a plurality of emission control lines EML.

The controller CTR can control driving operations of the data driver DDR and the gate driver GDR by supplying various types or levels of control signals (DCS and GCS) needed for driving operations of the data driver DDR and the gate driver GDR. The controller CTR can supply image data DATA to the data driver DDR.

The controller CTR can start to scan pixels according to timing scheduled in each frame. The controller CTR can convert image data received from an internal or external image providing source (e.g., a host system, or an internal or external image providing device or system) to image data DATA in a data signal form readable by the data driver DDR, and then output the image data DATA obtained by the converting to the data driver DDR. The controller CTR can control data driving so that data voltages corresponding to the image data DATA can be written into corresponding pixels at a preset scan time.

To control the data driver DDR and the gate driver GDR, the controller CTR can receive timing signals, such as, a vertical synchronization signal Vsync, a horizontal synchronization signal Hsync, an input data enable (DE) signal, a clock signal, and the like from the internal or external image providing source (e.g., the host system, or the internal or external image providing device or system), and generate various types or levels of control signals based on the received timing signals. Thereafter, the controller CTR can supply the generated signals to the data driver DDR and the gate driver GDR.

For example, to control the gate driver GDR, the controller CTR can output several types of gate control signals GCS including a gate start pulse, a gate shift clock, a gate output enable signal, and the like.

Further, to control the data driver DDR, the controller CTR can output several types of data control signals DCS including a source start pulse, a source sampling clock, a source output enable signal, and the like.

For example, the controller CTR can be a timing controller used in the display technology. The controller CTR can be a control apparatus or device capable of additionally performing one or more other control functions in addition to the function of the timing controller.

The controller CTR can be implemented in a separate component from the data driver DDR. The controller CTR can be integrated with the data driver DDR into an integrated circuit, so that the controller CTR and the data driver DDR can be implemented in a single integrated circuit.

The data driver DDR can drive a plurality of data lines DL by receiving image data DATA from the controller CTR and supplying data voltages corresponding to the image data to the plurality of data lines DL. The data driver DDR can be referred to as a data driving circuit, a source driving circuit, or a source driver.

The data driver DDR can transmit various signals to, or receive various signals from, the controller CTR through various interfaces.

The gate driver GDR can sequentially drive a plurality of gate lines GL by sequentially supplying scan signals to the plurality of gate lines GL. The gate driver GDR can be referred to as a gate driving circuit, a scan driving circuit, or a scan driver.

According to the control of the controller CTR, the gate driver GDR can sequentially supply scan signals representing an on-voltage or an off-voltage to the plurality of gate lines GL.

When a specific gate line is selected and driven by a scan signal from the gate driver GDR, the data driver DDR can convert image data DATA received from the controller CTR into analog data voltages and supply the obtained data voltages to the plurality of data lines DL.

The data driver DDR can be disposed in, and/or electrically connected to, but not limited to, one side or edge (e.g., an upper portion or a lower portion) of the display panel PLN. However, aspects of the present disclosure are not limited thereto. In some aspects, the data driver DDR can be disposed in, and/or electrically connected to, but not limited to, two sides or edges (e.g., an upper portion and a lower portion) of the display panel PLN or at least two of four sides or edges (e.g., the upper portion, the lower portion, a left portion, and a right portion) of the display panel PLN according to driving schemes, panel design schemes, or the like.

The gate driver GDR can be disposed in, and/or electrically connected to, but not limited to, one side or edge (e.g., a left portion or a right portion) of the display panel PLN. However, aspects of the present disclosure are not limited thereto. In some aspects, the gate driver GDR can be disposed in, and/or electrically connected to, but not limited to, two sides or edges (e.g., a left portion and a right portion) of the display panel PLN or at least two of four sides or edges (e.g., the left portion, the right portion, an upper portion, and a lower portion) of the display panel PLN according to driving schemes, panel design schemes, or the like.

The data driver DDR can be implemented by including one or more source driver integrated circuits SDIC.

Each source driver integrated circuit SDIC can include a shift register, a latch circuit, a digital-to-analog converter (DAC), an output buffer, and the like. In some aspects, the data driver DDR can further include one or more analog-to-digital converters (ADC).

Each source driver integrated circuit SDIC can be connected to a conductive pad such as a bonding pad of the display panel PLN by a tape-automated-bonding (TAB) technique or a chip-on-glass (COG) technique. Each source driver integrated circuit SDIC can be directly disposed in the display panel PLN. In some aspects, each source driver integrated circuit SDIC can be integrated into the display panel PLN in the form of an integrated circuit. In some aspects, each source driver integrated circuit SDIC can be connected to the display panel PLN by a chip-on-film (COF) technique. In this implementation, each source driver integrated circuit SDIC can be mounted on a circuit film. For example, each source driver integrated circuit SDIC mounted on the circuit film can be electrically connected to data lines DL in the display panel PLN through a circuit film.

The gate driver GDR can include a plurality of gate driving circuits GDC. The plurality of gate driving circuits GDC can correspond to a plurality of gate lines GL, respectively.

Each gate driving circuit GDC can include a shift register, a level shifter, and the like.

Each gate driving circuit GDC can be connected to a conductive pad such as a bonding pad of the display panel PLN by the tape-automated-bonding (TAB) technique or the chip-on-glass (COG) technique. In some aspects, each gate driving circuit GDC can be connected to the display panel PLN by the chip-on-film (COF) technique. In this implementation, each gate driving circuit GDC can be mounted on a circuit film. For example, each gate driving circuit GDC mounted on the circuit film can be electrically connected to gate lines GL in the display panel PLN through a circuit film. In some aspects, each gate driving circuit GDC can be embedded into the display panel PLN by a gate-in-panel (GIP) technique. In this implementation, each gate driving circuit GDC can be directly formed in the display panel PLN.

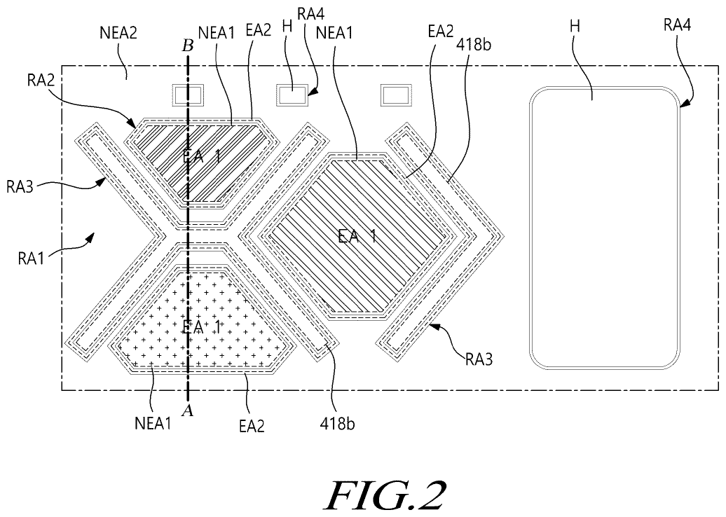

FIG. 2 is a plan view of an example portion of the active area A/A of the display device 100 according to aspects of the present disclosure.

Referring to FIG. 2, a plurality of light emitting areas EA and a plurality of non- light emitting areas NEA can be formed in the active area A/A.

The areas of respective light emitting areas EA of at least two subpixels SP can be different, but aspects of the present disclosure are not limited thereto.

In one or more aspects, the display device can include a plurality of light emitting areas (EA1 and EA2) and a plurality of non-light emitting areas (NEA1 and NEA2).

For example, the plurality of light emitting areas (EA1 and EA2) and the plurality of non-light emitting areas (NEA1 and NEA2) can be provided by one subpixel.

For example, the first and second light emitting areas (EA1 and EA2) can be located in one opening of a bank, and at least one first non-light emitting area NEA1 can be located in the one opening of the bank.

When the display device is in an on state, the first non-light emitting area NEA1 can be in a black state or in a state where light is emitted at a luminance lower than the first and second light emitting areas (EA1 and EA2) due to light coming from at least one of the first and second light emitting areas (EA1 and EA2).

In one or more aspects, each subpixel can have a structure in which a first non-light emitting area NEA1 can surround a first light emitting area EA1, a second light emitting area EA2 can surround the first non-light emitting area NEA1, and a second non-light emitting area NEA2 can surround the second light emitting area EA2.

The first light emitting area EA1, the first non-light emitting area NEA1, and the second light emitting area EA2, which are formed in one subpixel, can be configured to be spaced apart from another first light emitting area EA1, another first non-light emitting area NEA1, and another second light emitting area EA2, which are formed in another adjacent subpixel.

In one or more aspects, among first light emitting areas EA1 disposed in the display panel PLN, at least one first light emitting area EA1 can be an area for emitting red light, at least another first light emitting area EA1 can be an area for emitting green light, and at least further another first light emitting area EA1 can be an area for emitting blue light, but aspects of the present disclosure are not limited thereto.

In one or more aspects, a second light emitting area EA2 surrounding the first light emitting area EA1 emitting red light can emit red light, a second light emitting area EA2 surrounding the first light emitting area EA1 emitting green light can emit green light, and a second light emitting area EA2 surrounding the first light emitting area EA1 emitting blue light can emit blue light. However, colors of light emitted from second light emitting areas EA2 according to aspects of the present disclosure are not limited to this. For example, even when a second light emitting area EA2 surrounding the first light emitting area EA1 emitting red light emits red light, color coordinates of the first light emitting area EA1 can be different from color coordinates of the second light emitting area EA2.

First light emitting areas EA1, second light emitting areas EA2, and first non-light emitting areas NEA1 can have, for example, a hexagonal shape in a plan view. However, aspects of the present disclosure are not limited thereto. For example, first light emitting areas EA1, second light emitting areas EA2, and first non-light emitting areas NEA1 can have, in a plan view, a circular shape, an oval shape, a polygonal shape such as a triangle, square, or pentagon, or the like, or a shape resulting from combining two or more thereof.

A pair of first and second light emitting areas (EA1 and EA2) can be spaced apart from another pair of first and second light emitting areas (EA1 and EA2), and a second non-light emitting area NEA2 can be present between them.

Each second non-light emitting area NEA2 can be an area corresponding to all or at least part of a circuit part where circuit elements needed for driving the first and second light emitting areas (EA1 and EA2) are disposed.

At least one open area 418b can be disposed in a second non-light emitting area NEA2.

The at least one open area 418b (which can be referred to as a second open area as described below) can be an open area disposed in an insulating layer, and have a structure in which a plurality of bar shapes are connected in a plan view, as shown in FIG. 2.

In one or more aspects, the display device 100 can include at least one hole area H, and the at least one hole area H can be surrounded by the second non-light emitting area NEA2. Herein, the term “hole area” can also be referred to as a hole.

In one or more aspects, the display device 100 can include first resistance areas RA1, second resistance areas RA2, third resistance areas RA3, and fourth resistance areas RA4.

Each first resistance area RA1 can be disposed in a corresponding second non-light emitting area. The first resistance area RA1 can be not located in the first light emitting area EA1, the first non-light emitting area NEA1, and the second light emitting area EA2 included in each of the plurality of subpixels. In one or more aspects, the first resistance area RA1 can be not disposed in the at least one open area and the at least one hole H.

Each second resistance area RA2 can be configured to surround a corresponding one of the plurality of subpixels. Each second resistance area RA2 can be configured to overlap with a corresponding first non-light emitting area NEA1 and a corresponding second light emitting area EA2.

Each third resistance area RA3 can be disposed between adjacent subpixels among a plurality of subpixels. Each third resistance area RA3 can overlap with a portion of a corresponding open area. The third resistance area RA3 can overlap with a first width of the open area, but can be not overlapping with a second width.

Each fourth resistance area RA4 can be configured to surround a corresponding hole H. The fourth resistance area RA4 can overlap with an edge of the hole H.

For example, the first resistance area RA1 can correspond to a flat surface on which an organic layer 470 is disposed to be flat, and the second to fourth resistance areas (RA2, RA3, and RA4) can correspond to an inclined surface on which the organic layer 470 is disposed at a predetermined angle relative to the flat surface.

A slope of the inclined surface where the second resistance area RA2 is located can be less than a slope of the inclined surface where the third resistance area RA3 and the fourth resistance area RA4 are located.

As a slope of the inclined surface on which the organic layer 470 is disposed increases, a thickness of the stacked organic layer 470 can become thinner, and thereby, an area of the organic layer 470 can be reduced (i.e., an area is proportional to a thickness). As a result, a resistance value of the organic layer 470 can increase.

Accordingly, a resistance value of the third resistance area RA3 and a resistance value of the fourth resistance area RA4 can be greater than a resistance value of the first resistance area RA1 and a resistance value of the second resistance area RA2.

When the resistance value of the third resistance area RA3 increases, lateral leakage current flowing between subpixels can be prevented.

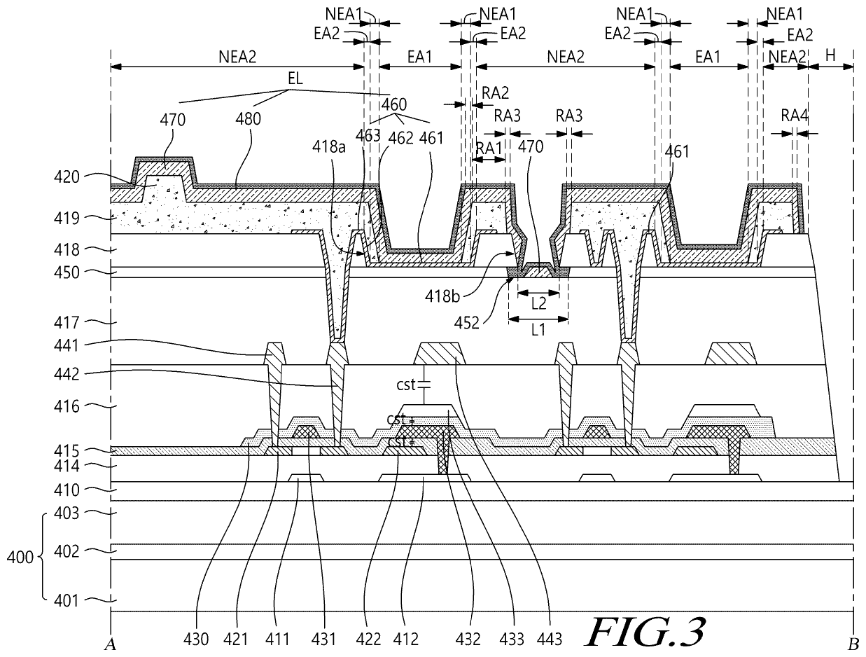

An example configuration for preventing lateral leakage current according to aspects of the present disclosure is discussed in more detail below with reference to FIG. 3.

FIG. 3 is an example cross-sectional view taken along line A-B of FIG. 2.

Referring to FIG. 3, a transistor TR disposed on a substrate 400 and a light emitting element EL electrically connected to the transistor TR can be disposed in a portion of the active area A/A (i.e., a cross-sectional area cut along line A-B).

At least one hole area H can be disposed in the active area A/A. For example, the hole area H can be an area where the substrate 400, the transistor TR, and the light emitting element EL are not disposed.

The transistor TR can include an active layer 421, a gate electrode 431, a source electrode 442, and a drain electrode 441.

The light emitting element EL such as an organic light emitting diode and the like can include a first electrode 460, an organic layer 470 including an emission layer, and a second electrode 480. In one or more aspects, the first electrode 460 can be an anode electrode, and the second electrode 480 can be a cathode electrode, but aspects of the present disclosure are not limited thereto.

The substrate 400 can include a first substrate 401 and a second substrate 403, and an intermediate layer 402 can be disposed between the first substrate 401 and the second substrate 403. For example, the intermediate layer 402 can be an inorganic layer, and can serve to shield the penetration of moisture. However, the structure of the substrate 400 according to aspects of the present disclosure is not limited to this. For example, the substrate 400 can have a single layer structure other than a multilayer structure.

A first buffer layer 410 can be disposed on the substrate 400, and can be a single layer or include multiple layers. A light shield 411 can be disposed on the first buffer layer 410. A second buffer layer 414 can be disposed on the light shield 411.

The active layer 421 and a first storage capacitor electrode 422 can be disposed on the second buffer layer 414. In one or more aspects, the active layer 421 can include a channel region, and the channel region can overlap with at least a portion of the light shield 411 and the gate electrode 431.

The remaining area excluding the channel region of the active layer 421 can be a region in which the active layer 421 is modified to become conductive (which can be referred to as a conductivity-enabled region). The active layer 421 can include an oxide semiconductor material.

The first storage capacitor electrode 422 can be disposed in the same layer as the active layer 421. The first storage capacitor electrode 422 can be in a conductivity-enabled state where an oxide semiconductor material is modified to become conductive, but aspects of the present disclosure are not limited thereto.

A gate insulating layer 415 can be disposed on the active layer 421 and the first storage capacitor electrode 422. The gate electrode 431 and a second storage capacitor electrode 432 can be disposed on the gate insulating layer 415.

The gate electrode 431 can overlap with the channel region of the active layer 421, and the second storage capacitor electrode 432 can overlap with the first storage capacitor electrode 422. The second storage capacitor electrode 432 can be electrically connected to a metal layer 412 disposed in the same layer as the light shield 411, but aspects of the present disclosure are not limited thereto.

An interlayer insulating layer 430 can be disposed on the gate electrode 431 and the second storage capacitor electrode 432. A third storage capacitor electrode 433 can be disposed on the interlayer insulating layer 430. The third storage capacitor electrode 433 can overlap with the second storage capacitor electrode 432.

A protective layer 416 can be disposed on the third storage capacitor electrode 433. The protective layer 416 can include an organic insulating material or an inorganic insulating material.

The source electrode 442, the drain electrode 441, and a fourth storage capacitor electrode 443 can be disposed on the protective layer 416. The source electrode 442 and the drain electrode 441 can be configured to be spaced apart from each other and be electrically connected to the conductivity-enabled region of the active layer 421.

The fourth storage capacitor electrode 443 can overlap with the third storage capacitor electrode 433.

The first to fourth storage capacitor electrodes (422, 432, 433, and 443) can be configured to overlap with each other, and can form a storage capacitor Cst.

A first insulating layer 417 can be disposed on the source electrode 442, the drain electrode 441, and the fourth storage capacitor electrode 443. The first insulating layer 417 can serve to planarize the surface of the substrate 400.

A disconnection inducing layer 450 can be disposed on the first insulating layer 417. The disconnection inducing layer 450 can include an inorganic insulating material, but aspects of the present disclosure are not limited thereto.

The disconnection inducing layer 450 can include a first open area 452 exposing a portion of the upper surface of the first insulating layer 417 in an area corresponding to a second non-light emitting area NEA2.

A second insulating layer 418 can be disposed on the disconnection inducing layer 450.

The thickness of the disconnection inducing layer 450 can be less than a thickness of each of the first and second insulating layers (417 and 418).

The second insulating layer 418 can include one hole in an area overlapping a portion of the upper surface of the source electrode 442 or drain electrode 441 of the transistor.

In one or more aspects, the second insulating layer 418 can include an opened portion 418a exposing a portion of the upper surface of the disconnection inducing layer 450.

In one or more aspects, the second insulating layer 418 can include a second open area 418b overlapping with a portion of the first open area 452 of the disconnection inducing layer 450.

In the cross-sectional view shown in FIG. 3, a first width L1 of the first open area 452 can be larger than a second width L2 of the second open area 418b. Here, each of the first and second widths (L1 and L2) can mean a shortest length in a direction perpendicular to a direction in which the first buffer layer 410 is stacked over the substrate 400.

Accordingly, a portion of the second insulating layer 418 can overlap with a portion of the first open area 452 of the disconnection inducing layer 450.

An edge of the first open area 452 can be covered by the second insulating layer 418. For example, as shown in FIG. 3, an undercut structure can be formed at the edge of the first open area 452.

The undercut structure formed by the disconnection inducing layer 450 and the second insulating layer 418 can be located between light emitting areas emitting light of different colors. For example, at least one undercut structure can be disposed in a portion of the second non-light emitting area NEA2 between light emitting areas (EA1 and EA2) emitting red light and light emitting areas (EA1 and EA2) emitting green light. However, this is only an example, and any configuration in which at least one undercut structure is disposed in the second non-light emitting area NEA2 of the active area A/A can be sufficient to meet aspects of the present disclosure.

The first electrode 460 of the light emitting element EL can be disposed on the second insulating layer 418.

The first electrode 460 can include a first area 461 where the upper surface of the first electrode 460 is parallel to the surface of the substrate 400 in an area overlapping with the opened portion 418a, and a second area 462 extending from the first area 461 and being an area where the upper surface of the first electrode 460 has a predetermined angle relative to the substrate 400. For example, the surface of the second area 462 may not be parallel to the surface of the substrate 400. In one or more aspects, the first electrode 460 can include a third area 463 extending from the second area 462 and being an area where the upper surface of the first electrode 460 is parallel to the surface of the substrate 400. The third area 463 can be an area overlapping with a portion of the upper surface of the second insulating layer 418, but not overlapping with the hole, the opened portion 418a, and the second open area 418b of the second insulating layer 418.

In one or more aspects, in at least one subpixel area, the transistor TR and the first electrode 460 of the light emitting element EL can be electrically connected through the hole of the second insulating layer 418.

A bank 419 can be disposed on a portion of the second insulating layer 418 and the first electrode 460.

A spacer 420 can be disposed on a portion of the upper surface of the bank 419. The spacer 420 can be disposed in the second non-light emitting area NEA2.

The bank 419 can be configured to expose a portion of the upper surface of the first electrode 460 disposed in the opened portion 418a of the second insulating layer 418. In one or more aspects, the bank 419 can be not overlapping with the first and second open areas (452 and 418b).

The organic layer 470 of the light emitting element EL can be disposed over the substrate 400 over which the bank 419 is disposed.

The organic layer 470 can be disconnected in an area where the first open area 452 and the second insulating layer 418 overlap with each other.

For example, the organic layer 470 can be disposed on the upper surface of the bank 419, the upper surface of the first electrode 460, and the upper surface of the first insulating layer 417 in an area overlapping with the second open area 418b. Further, the organic layer 470 can be not disposed on, or on the upper surface of, the disconnection inducing layer 450 in an area where the first open area 452 of the disconnection inducing layer 450 and the second insulating layer 418 overlap with each other.

When a first subpixel is in an on state and a second subpixel adjacent to the first subpixel is in an off state, only light emitting areas included in the first subpixel are needed to emit light.

However, when the organic layer (e.g., an organic common layer) is continuously disposed without a disconnected portion in the active area A/A, even when only the first subpixel is in the on state, there can occur a situation where the adjacent second subpixel emits light due to leakage current.

In one or more aspects, in the display device 100, the organic layer 470 can be not disposed in at least a portion of the second non-light emitting area NEA2 located between two different subpixels, and thereby, one or more adjacent subpixels in an off state can be prevented from emitting light due to leakage current.

The second electrode 480 of the light emitting element EL can be disposed over the substrate 400 over which the organic layer 470 is disposed.

The second electrode 480 can be disposed in all of at least one first light emitting area EA1, at least one first non-light emitting area NEA1, at least one second light emitting area EA1, and at least one second non-light emitting area NEA2.

For examples, the second electrode 480 can be disposed on the upper surface of the organic layer 470, and also be disposed in an area where the first open area 452 and the second insulating layer 418 overlap with each other and an area where the organic layer 470 is not disposed.

The first electrode 460 of the light emitting element EL can include at least one of aluminum (Al), neodymium (Nd), nickel (Ni), titanium (Ti), tantalum (Ta), copper (Cu), silver (Ag), and aluminum alloy, but aspects of the present disclosure are not limited thereto.

The second electrode 480 can include a conductive material allowing light to be transmitted fully or partly. For example, the second electrode 480 can include at least one of transparent conductive oxides, such as indium tin oxide (ITO), indium zinc oxide (IZO), indium tin zinc oxide (ITZO), zinc oxide, tin oxide, and the like, or include a semi-transmissive metal, such as magnesium (Mg), silver (Ag), or an alloy of Mg and Ag. In an example where the second electrode 480 includes a semi-transmissive metal, a thickness of the second electrode 480 can be less than that of the first electrode 460.

At least one subpixel SP can include at least one light emitting area EA, and the at least one light emitting area EA can include at least two light emitting areas (EA1 and EA2). One non-light emitting area NEA1 can be disposed between the two light emitting areas (EA1 and EA2).

In one or more aspects, a first light emitting area EA1 in FIG. 3 can be an area corresponding to a portion of the opened portion 418a of the second insulating layer 418.

In one or more aspects, the first light emitting area EA can an area overlapping with a portion of the first electrode 460 disposed in the opened portion 418a and corresponding to an area where the opened portion 418a and the bank 419 do not overlap with each other.

The first light emitting area EA1 can be an area where some of light emitted from the organic layer 470 is directed outside of the display panel through the organic layer 470 and the second electrode 480.

In one or more aspects, the first light emitting area EA1 can be an area where some light (which can be referred to as first light) among light emitted from the organic layer 470 reaches the first electrode 460, is reflected from the first electrode 460, and thereafter, is directed outside of the display panel through the organic layer 470 and the second electrode 480.

The first light emitting area EA1 can be surrounded by a first non-light emitting area NEA1.

The first non-light emitting area NEA1 can correspond to an area where the bank 419 overlaps with the opened portion 418a and the first electrode 460, and where an area (hereinafter, which can be referred to as a flat portion) where the upper surface of the first electrode 460 is disposed parallel to the surface of the substrate 400 is located. For example, the first non- light emitting area NEA1 can be an area where the bank 419 overlaps with the opened portion 418a and the first electrode 460, and where an area corresponding to an inclined surface of the opened portion 418a is excluded.

The first non-light emitting area NEA1 can be an area where some light among light emitted from the organic layer 470 is directed in a direction parallel to the flat portion of the first electrode 460, reaches the first electrode 460, and thereafter, is trapped in the subpixel without being reflected from the first electrode 460 to be directed outside of the display panel.

A second light emitting area EA2 can be configured to surround the first non-light emitting area NEA1. The second light emitting area EA2 can be an area corresponding to an area where the first electrode 460 overlaps with the inclined surface of the opened portion 418a of the second insulating layer 418. In one or more aspects, the second light emitting area EA2 can be an area corresponding to the second area 462 of the first electrode 460.

Some light (which can be referred to as second light) among light emitted from the organic layer 470 can move to an area corresponding to the second area 462 of the first electrode 460.

For example, second light can pass through the bank 419 and reach an area corresponding to a portion of the second area 462 of the first electrode 460. The second light reaching the first electrode 460 can be reflected by the first electrode 460 and directed outside of the display panel through the bank 419, the organic layer 470, and the second electrode 480.

The first non-light emitting area NEA1 located between the first light emitting area EA1 and the second light emitting area EA2 can be an area where both visible light of the first light emitting area EA1 and visible light of the second light emitting area EA2 are present, but aspects of the present disclosure are not limited thereto.

A second non-light emitting area NEA2 can be configured to surround the second light emitting area EA2. The second non-light emitting area NEA2 can correspond to the remaining area of the active area A/A excluding a plurality of first light emitting areas EA1, a plurality of second light emitting areas EA2, and a plurality of first non-light emitting areas NEA1 formed in the active area A/A.

The second non-light emitting area NEA2 can include first and second open areas (452 and 418b).

In one or more aspects, the display device can include at least one hole area H.

The hole area H can include an area where a portion of at least one insulating layer (for example, the first buffer layer 410) disposed on the substrate 400 is disposed.

Although FIGS. 2 and 3 illustrate that the second open area 418b has a structure in which a plurality of bars (or bar shapes) are connected in a plan view, but aspects of the present disclosure are not limited thereto.

Referring to FIG. 3, a first resistance area RAI can correspond to a flat surface of the organic layer 470, in which the organic layer 470 is evenly formed. For example, the first resistance area can correspond to a flat surface of the bank 419, a flat surface of the spacer 420, and the like.

A second resistance area RA2 can correspond to an inclined surface of the organic layer 470, in which the organic layer 470 is stacked on a side surface (e.g., an inclined surface) of the bank 419 in an opening of the bank 419. The second resistance area RA2 can be configured to overlap with the first non-light emitting area NEA1 and the second light emitting area EA2. A portion of the organic layer 470 stacked on the inclined surface in the opening can have a thickness less than a portion of the organic layer 470 stacked on the flat surface. Accordingly, a resistance value of the second resistance area RA2 can be greater than a resistance value of the first resistance area RA1.

A third resistance area RA3 can correspond to an inclined surface of the organic layer 470, in which the organic layer 470 is stacked on a side surface (e.g., an inclined surface) of the bank 419 disposed in the first open area 452.

The third resistance area RA3 can overlap with a portion of the first open area 452. The third resistance area RA3 can be not overlapping with the second width L2 of the second open area 418b, but can overlap with a portion of the first width L1 of the first open area 452. The inclined surface of the bank 419 in the first open area 452 can have a slope greater than the inclined side surface of the bank 419 in the opening. The organic layer 470 stacked on the inclined surface of the bank 419 in the first open area 452 can have a thickness less than the organic layer 470 stacked on the inclined surface in the opening. Accordingly, a resistance value of the third resistance area RA3 can be greater than a resistance value of the second resistance area RA2.

When the resistance value of the third resistance area RA3 is greater than the resistance values of the first resistance area RA1 and the second resistance area RA2, lateral leakage current flowing between subpixels can be prevented.

A fourth resistance area RA4 can correspond to an inclined surface of the organic layer 470, in which the organic layer 470 is stacked on a side surface (e.g., an inclined surface) of the bank 419 disposed adjacent to the hole H. The fourth resistance area RA4 can overlap with an edge of the hole H. The inclined surface of the bank 419 disposed adjacent to the hole H can have a slope greater than the inclined surface of the bank 419 in the opening. A portion of the organic layer 470 stacked on the inclined surface of the bank 419 disposed adjacent to the hole H can have a thickness less than a portion of the organic layer 470 stacked on the inclined surface of the bank 419 in the opening. Accordingly, a resistance value of the fourth resistance area RA4 can be greater than that of the second resistance area RA2.

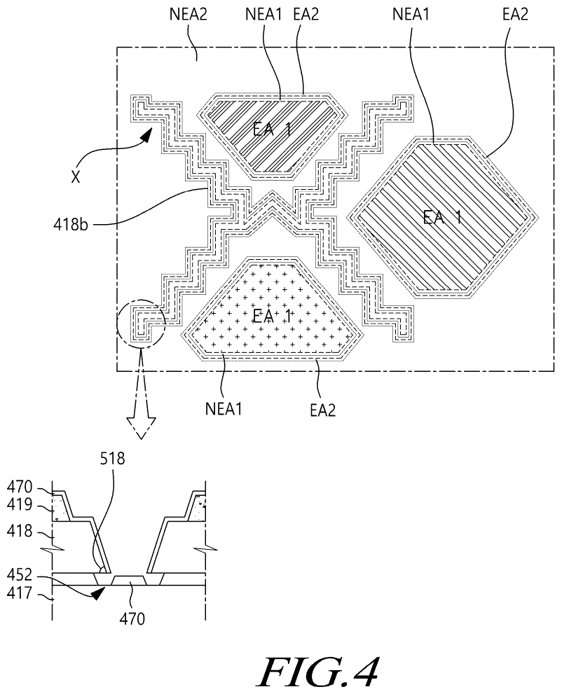

FIG. 4 schematically illustrates an example portion of the active area of the display device according to aspects of the present disclosure.

Referring to FIG. 4, a second open area 418b can be disposed between light emitting areas emitting light of different colors.

In a plan view, the second open area 418b can be configured to surround an outer edge of each of a second light emitting area EA2 emitting red light, a second light emitting area EA2 emitting green light, and a second light emitting area EA emitting blue light.

The second open area 418b located in the active area A/A can be disposed in a portion of a second non-light emitting area NEA2 and can include a plurality of bent portions X.

In areas corresponding to the bent portions X of the second open area 418b, as shown in FIG. 4, a taper angle 518 of the second insulating layer 418 in an area overlapping with a first open area 452 can be formed to be 60° to 80°. Accordingly, a slope of a side surface of the second insulating layer 418 in the area corresponding to the second open area 418b can be greater than that of the structure of FIG. 2.

A thickness of the organic layer 470 disposed on the side surface of the second insulating layer 418 overlapping with the first open area 452 can become thinner as the taper angle 518 of the second insulating layer 418 is formed to be 60° to 80°. Accordingly, the organic layer 470 may not be formed under the second insulating layer 418 in an area where the first open area 452 overlaps with the second insulating layer 418.

In addition, as a thickness of the organic layer 470 disposed on the side surface of the second insulating layer 418 overlapping with the first open area 452 becomes thinner, an area of the organic layer 470 can be reduced (i.e., the area is proportional to the thickness). Thereby, a resistance value of the organic layer 470 can increase. As the resistance value of the organic layer 470 increases, the organic layer 470 disposed on the side surface of the second insulating layer 418 overlapping with the first open area 452 can be caused not to emit light.

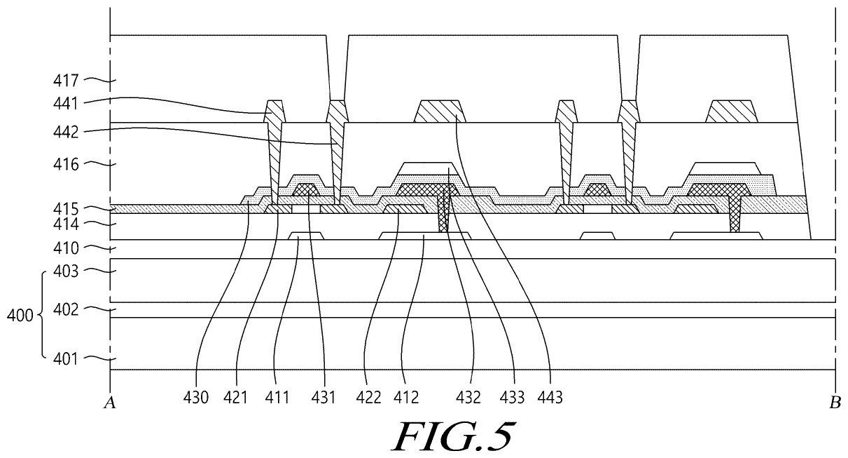

FIGS. 5 to 9 schematically illustrate an example method of manufacturing the display device according to aspects of the present disclosure.

Referring to FIG. 5, a first buffer layer 410 can be disposed on a substrate 400.

A light shield 411 and a metal layer 412 can be disposed on the first buffer layer 410.

A second buffer layer 414 can be disposed over the substrate 400 on which the first buffer layer 410, the light shield 411, and the metal layer 412 are disposed.

An active layer 421 and a first storage capacitor electrode 422 can be disposed on the second buffer layer 414.

A gate insulating layer 415 can be disposed over the substrate 400 over which the active layer 421 and the first storage capacitor electrode 422 are disposed.

A gate electrode 431 and a second storage capacitor electrode 432 can be disposed on the gate insulating layer 415.

An interlayer insulating layer 430 can be disposed on the gate electrode 431 and the second storage capacitor electrode 432.

A third storage capacitor electrode 433 can be disposed on the interlayer insulating layer 430.

A protective layer 416 can be disposed on the third storage capacitor electrode 433.

A source electrode 442, a drain electrode 441, and a fourth storage capacitor electrode 443 can be disposed on the protective layer 416.

A first insulating layer 417 can be disposed on the source electrode 442, the drain electrode 441, and the fourth storage capacitor electrode 443.

A hole (hereinafter, which can be referred to as a first contact hole) can be formed in the first insulating layer 417 and expose at least a portion of the upper surface of the source electrode 442 of a corresponding transistor.

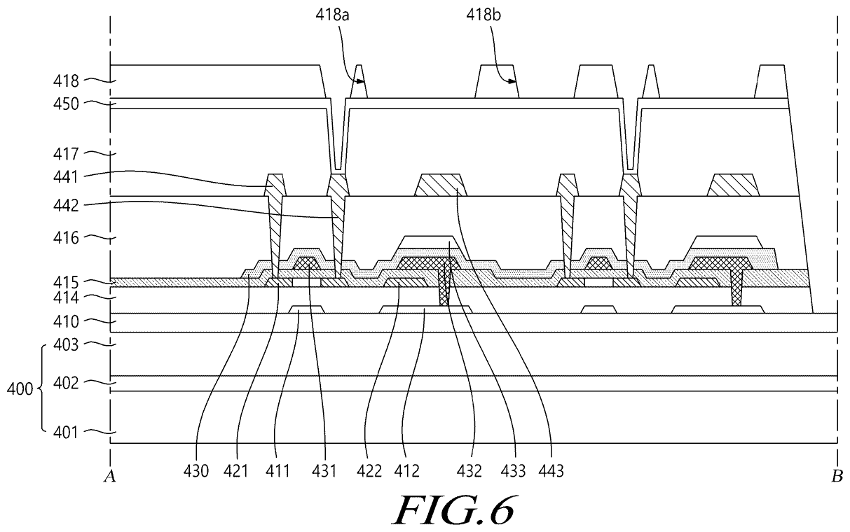

Referring to FIG. 6, a disconnection inducing layer material 650 can be formed on the first insulating layer 417.

The disconnection inducing layer material 650 can be disposed inside of the first contact hole of the first insulating layer 417 and contact the top surface of the source electrode 442.

A second insulating layer 418 can be formed on the disconnection inducing layer material 650.

The second insulating layer 418 can include a second contact hole in an area corresponding to the first contact hole of the first insulating layer 417.

The second insulating layer 418 can include an opened portion 418a and a second open area 418b spaced apart from the opened portion 418a.

The opened portion 418a and the second open area 418b of the second insulating layer 418 can expose respective portions of the upper surface of the disconnection inducing layer material 650.

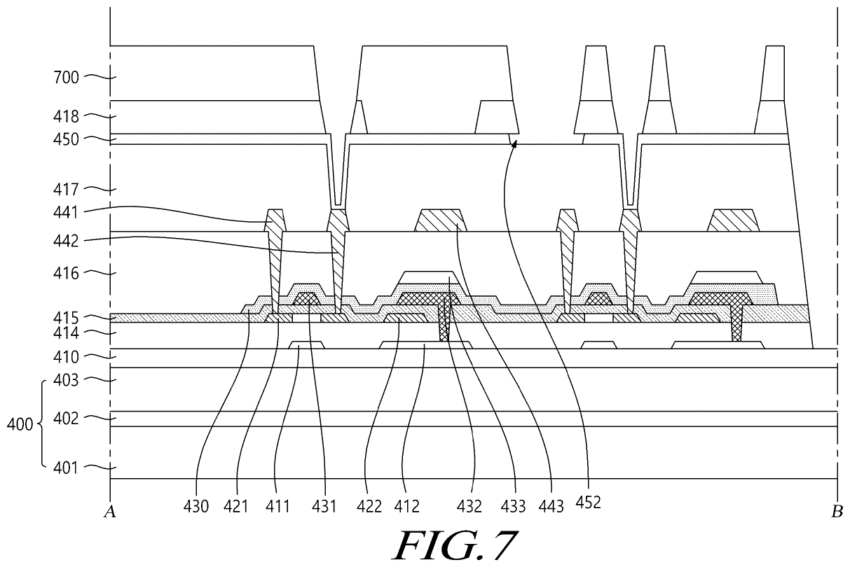

Thereafter, referring to FIG. 7, a photoresist pattern 700 can be disposed on the second insulating layer 418.

The photoresist pattern 700 can include at least two holes in one subpixel area. One hole among the at least two holes of the photoresist pattern 700 can be located in an area overlapping with the first contact hole of the first insulating layer 417 and the second contact hole of the second insulating layer 418, which are configured to overlap with the source electrode 442 of the transistor.

The other hole of the photoresist pattern 700 can be located in an area overlapping with the second open area 418b of the second insulating layer 418.

The disconnection inducing layer material 650 can be patterned through a photolithography process using the photoresist pattern 700 as a mask.

For example, the portions of the disconnection inducing layer material 650 disposed in areas corresponding to holes of the photoresist pattern 700 can be patterned and removed.

Through this process, the disconnection inducing layer 450 can be formed, and the disconnection inducing layer 450 can be not disposed in the area overlapping the source electrode 442 of the transistor. The disconnection inducing layer 450 can be not disposed in the area overlapping the second open area 418b of the second insulating layer 418.

The disconnection inducing layer 450 can include a first open area 452 in an area overlapping with the second open area 418b. An area where the first open area 452 overlaps with the upper surface of the first insulating layer 417 can be greater than an area where the second open area 418b overlaps with the upper surface of the first insulating layer 417.

The photoresist pattern 700 disposed on the second insulating layer 418 can be removed.

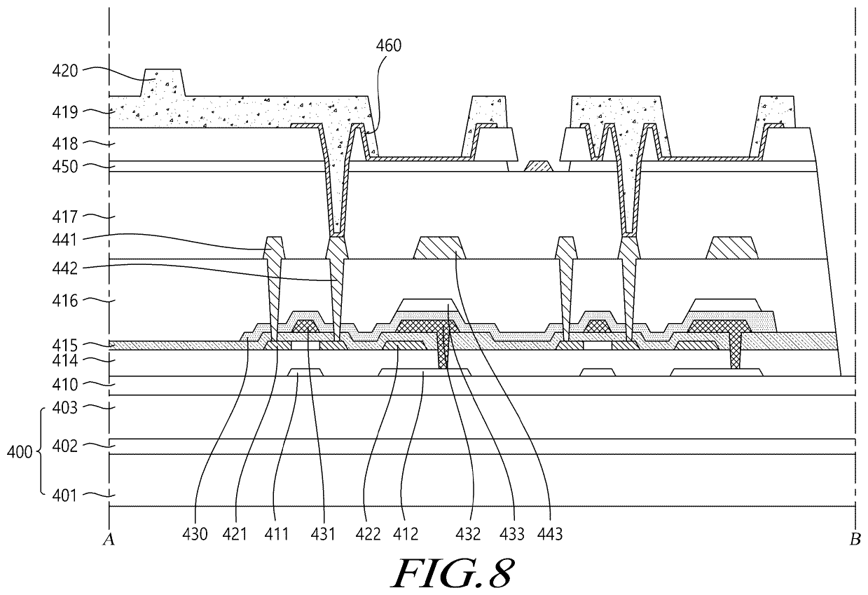

Referring to FIG. 8, a first electrode 460 of a light emitting element can be disposed. The first electrode 460 can contact the upper surface of the source electrode 442 of the transistor and be disposed in the opened portion 418a of the second insulating layer 418.

A bank 419 and a spacer 420 can be disposed over the substrate 400 over which the first electrode 460 is disposed.

The bank 419 can expose the upper surface of the first electrode 460 in a portion of the opened portion 418a of the second insulating layer 418 and include a hole in an area corresponding to the second open area 418b.

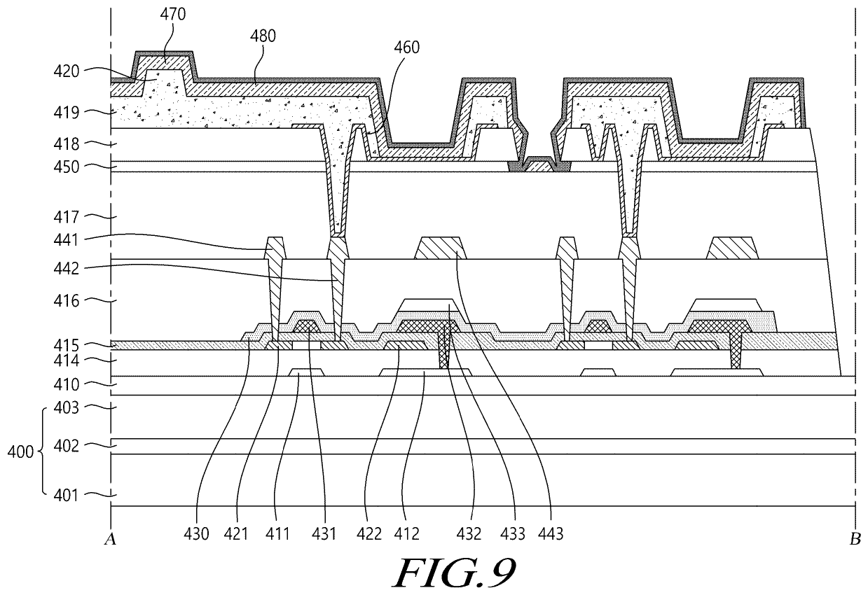

Thereafter, referring to FIG. 9, an organic layer 470 and a second electrode 480 of the light emitting element can be sequentially disposed over the substrate 400.

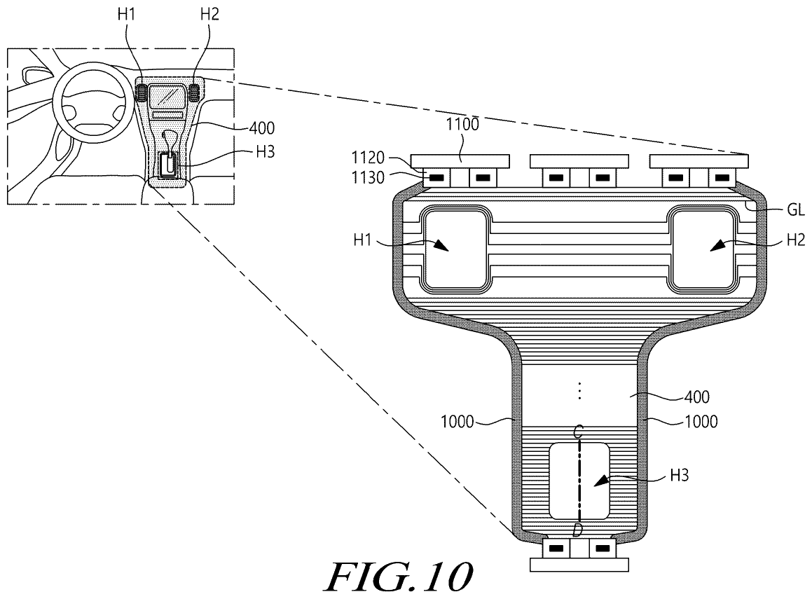

The display device manufactured by the process discussed above can be used in various ways. For example, this display device can be used as a vehicle display device, which is discussed below with reference to FIGS. 10 to 14.

FIGS. 10 to 13 illustrate an example structure to which the display device is applied according to aspects of the present disclosure.

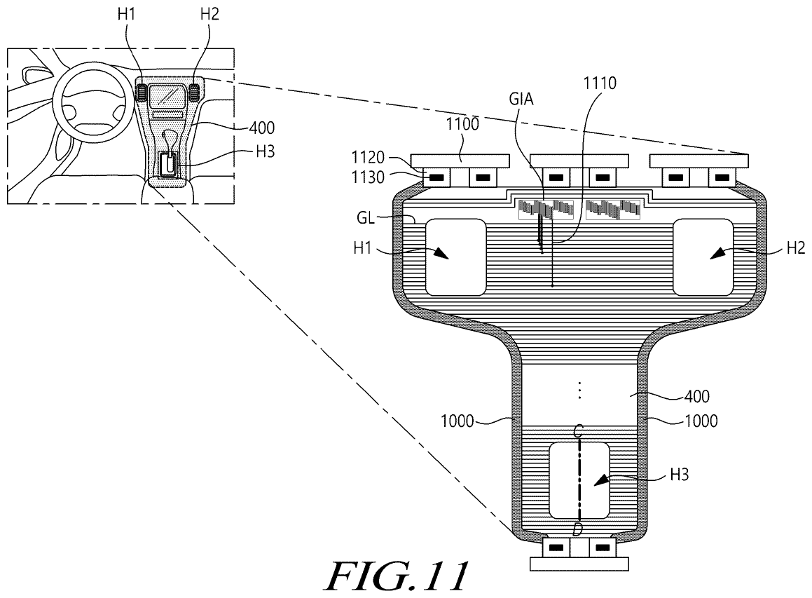

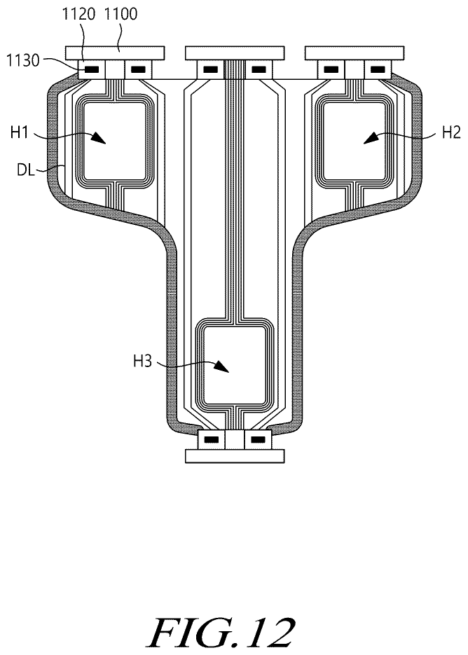

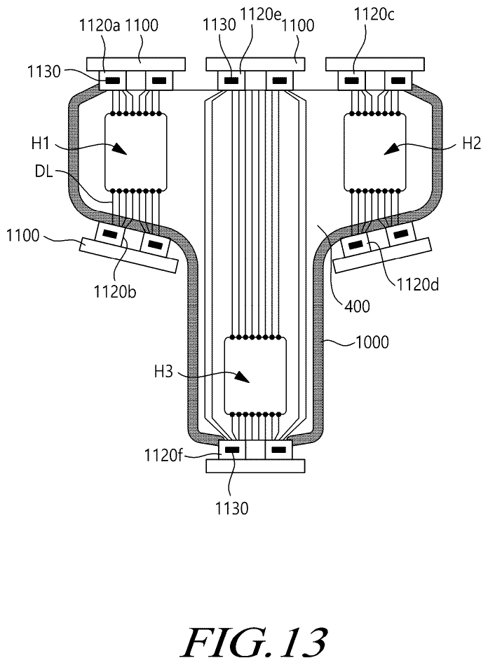

Particularly, FIGS. 10 and 11 schematically illustrate gate lines GL disposed on a substrate 400 and locations of holes H in the substrate 400, and FIGS. 12 and 13 schematically illustrate data lines DL disposed on the substrate 400 and locations of holes H in the substrate 400.

Referring to FIGS. 10 and 11, in one or more aspects, the display device can be used as a vehicle display device.

In one or more aspects, the substrate 400 can be provided with at least one hole H.

For example, the substrate 400 can be provided with three holes (H1, H2, and H3).

The substrate 400 can be provided with a first hole H1, a second hole H2, and a third hole H3. The first hole H1, the second hole H2, and the third hole H3 can be configured to be spaced apart from each other. Components included in an associated vehicle can be placed in the first hole H1, the second hole H2, and the third hole H3.

For example, the first and second holes (H1 and H2) can be arranged side by side in one direction. The remaining third hole H3 can be disposed between the first hole H1 and the second hole H2.

A plurality of circuit boards 1100 and a plurality of circuit films 1120 can be disposed in an edge of the substrate 400. At least one chip 1130 can be mounted on each circuit film 1120.

In one or more aspects, except for the first to third holes (H1, H2, and H3), routing lines 1000, and a pad area disposed in an edge of the substrate 400 and including pad electrodes electrically connected to the circuit films 1120, all or most of the remaining area can be an active area A/A.

For example, each of the first to third holes (H1, H2, and H3) can be surrounded by the active area A/A.

All or at least part of the active area A/A of FIGS. 10 and 11 can include the stack-up configuration of FIG. 3.

Referring to FIGS. 10 and 11, a plurality of gate lines GL can be disposed on the substrate 400.

Referring to FIG. 10, the plurality of gate lines GL can be configured to extend from one side of the substrate 400 to another opposing side of the substrate 400. The plurality of gate lines GL can be connected to routing lines 1000 arranged along an edge of the substrate. The routing lines 1000 to which the plurality of gate lines GL are connected can be electrically connected to a circuit area disposed in a non-active area of the substrate.

In one or more aspects, one or more of the plurality of gate lines GL can be configured to bypass at least one of the first to third holes (H1, H2, and H3).

For example, among the plurality of gate lines GL, at least one gate line GL can be configured to bypass the first and second holes (H1 and H2), at least another gate line GL can be configured to bypass the third hole H3, and at least further another gate lines GL can be configured to extend from one side of the substrate 400 to another opposing side of the substrate 400 without bypassing the first to third holes (H1, H2, and H3).

In one or more aspects, referring to FIG. 11, among the plurality of gate lines GL disposed on the substrate 400, at least one gate line GL can be configured to extend from one side of the substrate 400 to another opposing side of the substrate 400. The at least one gate line GL can be electrically connected to at least one routing line 1000 disposed along an edge of the substrate 400.

In one or more aspects, referring to FIG. 11, a gate-in-array (GIA) area in which a gate driving circuit is disposed can be disposed in a portion of the active area A/A of the substrate 400. In one or more aspects, at least one gate lines GL among the gate lines GL can be configured to extend from one side of the substrate 400 to another opposing side of the substrate 400 and also include a portion of bypassing the GIA area.

In one or more aspects, a plurality of gate lines GL disposed between the first hole H1 and the second hole H1 can be electrically connected to at least one connection line 1110, and the at least one connection line 1110 can be electrically connected to a gate driving circuit disposed in the GIA area.

In one or more aspects, a plurality of gate lines GL disposed between one side of the substrate 400 (e.g., one side of the substrate 400 on which a circuit film 1120 is not disposed in FIG. 11) and the first hole H1 can be electrically connected to routing lines 1000, and a plurality of gate lines GL disposed between another opposing side of the substrate 400 (e.g., another opposing side of the substrate 400 on which a circuit film 1120 is not disposed in FIG. 11) and the second hole H2 GL can be electrically connected to routing lines 1000. In one or more aspects, a plurality of gate lines GL disposed between one side of the substrate 400 and the third hole H3 and a plurality of gate lines GL disposed between another opposing side of the substrate 400 and the third hole H3 can be electrically connected to routing lines 1000.

Accordingly, even when the first to third holes (H1, H2, and H3) are disposed in the substrate 400, a plurality of gate lines GL can be disposed on the substrate 400 without electrical disconnection.

Referring to FIGS. 12 and 13, a plurality of data lines DL can be disposed on the substrate 400.

The plurality of data lines DL can be configured to intersect the plurality of gate lines GL shown in FIGS. 10 and 11. The plurality of data lines DL can be electrically connected to circuit films 1120 electrically connected to the pad area of the substrate 400.

The data lines DL can be arranged in various ways on the substrate 400.

For example, referring to FIG. 12, one or more of the plurality of data lines DL can be configured to extend from one side of the substrate 400 on which a circuit film 1120 is disposed to another opposing side of the substrate 400 on which another circuit film 1120 is disposed.

In one or more aspects, the first hole H1, the second hole H2, or the third hole H3 can be disposed in a direction in which one or more of the plurality of data lines DL extend. In this implementation, as shown in FIG. 12, each of the one or more data lines DL can include a respective portion of bypassing the first hole H1, the second hole H2, or the third hole H3.

In one or more aspects, referring to FIG. 13, one or more data lines DL among data lines DL extending in a direction in which the first hole H1 is disposed can be disposed between the first hole H1 and a first circuit film 1120a. In this implementation, the one or more data lines DL disposed between the first hole H1 and the first circuit film 1120a can be electrically connected to the first circuit film 1120a. In one or more aspects, one or more other data lines DL among the data lines DL extending in the direction in which the first hole H1 is disposed can be disposed between the first hole H1 and a second circuit film 1120b. In this implementation, the one or more other data lines DL disposed between the first hole H1 and the second circuit film 1120b can be electrically connected to the second circuit film 1120b.

For example, the first circuit film 1120a and the second circuit film 1120b can be configured to be spaced apart from each other and can be arranged in parallel to each other in a direction in which data lines DL extends.

One or more data lines DL among data lines DL extending in a direction in which the second hole H2 is disposed can be disposed between the second hole H2 and a third circuit film 1120c. In this implementation, the one or more data lines DL disposed between the second hole H2 and the third circuit film 1120c can be electrically connected to the third circuit film 1120c. In one or more aspects, one or more other data lines DL among the data lines DL extending in the direction in which the second hole H2 is disposed can be disposed between the second hole H2 and a fourth circuit film 1120d. In this implementation, the one or more other data lines DL disposed between the second hole H2 and the fourth circuit film 1120d can be electrically connected to the fourth circuit film 1120d.

For example, the third circuit film 1120c and the fourth circuit film 1120d can be configured to be spaced apart from each other and can be arranged in parallel to each other in a direction in which data lines DL extends.

One or more data lines DL among data lines DL extending in a direction in which the third hole H3 is disposed can be disposed between the third hole H3 and a fifth circuit film 1120e. In this implementation, the one or more data lines DL disposed between the third hole H3 and the fifth circuit film 1120e can be electrically connected to the fifth circuit film 1120e. In one or more aspects, one or more other data lines DL among the data lines DL extending in the direction in which the third hole H3 is disposed can be disposed between the third hole H3 and a sixth circuit film 1120f. In this implementation, the one or more other data lines DL disposed between the third hole H3 and the sixth circuit film 1120f can be electrically connected to the sixth circuit film 1120f.

For example, the fifth circuit film 1120e and the sixth circuit film 1120f can be configured to be spaced apart from each other and can be arranged in parallel to each other in a direction in which data lines DL extends.

In this manner, even when the substrate 400 is provided with the plurality of holes (H1, H2, and H3), a plurality of gate lines GL and a plurality of data lines DL can be arranged in various structures. Through these configurations, in the substrate 400 including the plurality of holes (H1, H2, and H3), an area of the active area A/A including a plurality of light emitting areas can be expanded.

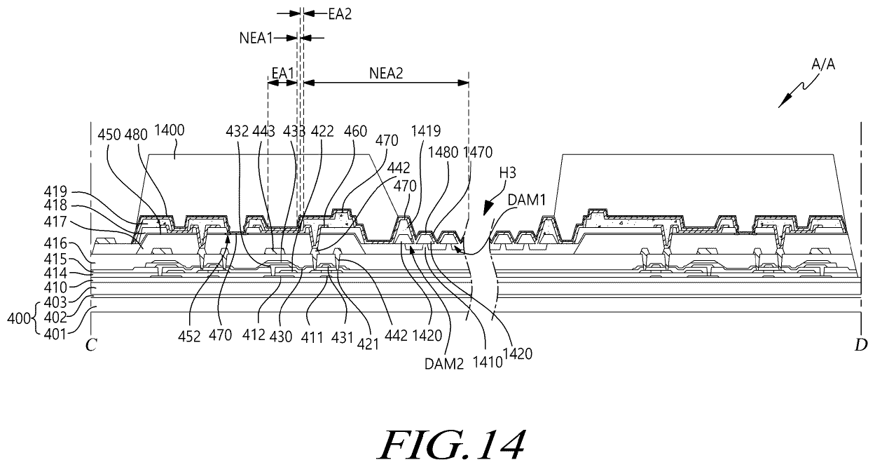

FIG. 14 is a cross-sectional view taken along line C-D of FIG. 10.

Hereinafter, discussions on some configurations, structures, and effects to which discussions provided above are applied equally, substantially equally, or mutatis mutandis may not be repeatedly provided for convenience of description. It should be, however, understood that the scope of the present disclosure includes such omitted configurations already discussed above. Further, in discussions that follow, like reference numerals are used for configurations or elements equal to, or substantially or nearly equal to, the configurations or elements described above.

Referring to FIG. 14, in one or more aspects, a plurality of transistors, a plurality of storage capacitors Cst, and a plurality of light emitting elements EL can be disposed on the substrate 400, and an encapsulation layer 1400 can be disposed on second electrodes 480 of the light emitting elements.

Particularly, FIG. 14 illustrates a structure in which the encapsulation layer 1400 is a single layer, but aspects of the present disclosure are not limited thereto. For example, the encapsulation layer 1400 can include at least two or more encapsulation layers. In one or more aspects, at least one of the at least two or more layers included in the encapsulation layer 1400 can include an organic material or an inorganic material.

Referring to FIG. 14, in one or more aspects, the active area A/A of the display device can include a plurality of light emitting areas, a plurality of non-light emitting areas, and at least one hole H3 (e.g., the third hole in FIG. 10).

For example, at least two light emitting areas (EA1 and EA2) and at least two non-light emitting areas (NEA1 and NEA2) can be formed in at least one subpixel disposed in the active area A/A.

An edge of the third hole H3 can be surrounded by a second non-light emitting area NEA2.

In one or more aspects, the second non-light emitting area NEA2 can include an area where a plurality of dams (DAM1 and DAM2) are disposed. For example, a plurality of first dams DAM1 and at least one second dam DAM2 can be disposed in at least a portion of the second non-light emitting area NEA2 surrounding the third hole H3. For example, the second dam DAM2 can be closer to the light emitting areas (EA1 and EA2) than the first dams DAM1. The second dam DAM2 can have, for example, a height greater than that of at least one of the first dams DAM1.

In one or more aspects, the structure of the first dams DAM1 can be described as follows. A disconnection inducing layer 450 can be disposed a gate insulating layer 415 in the second non-light emitting area NEA2 adjacent to the third hole H3. In the second non-light emitting area NEA2 adjacent to the third hole H3, the disconnection inducing layer 450 can have a plurality of protruding portions 1410. In this implementation, the plurality of protruding portions 1410 can be formed integrally with the disconnection inducing layer 450 as one piece.

The plurality of protruding portions 1410 can be configured to be spaced apart from each other.

A second insulating layer pattern 1420 can be disposed on a corresponding one of the plurality of protruding portions 1410. An organic layer pattern 1470 and a second electrode pattern 1480 can be disposed on the second insulating layer pattern 1420.

In one or more aspects, a width of each of the plurality of protruding portions 1410 can be less than that of the second insulating layer pattern 1420, and thereby, a structure in which each protruding portion 1410 and each second insulating layer pattern 1420 are stacked can be reversely tapered toward the substrate 400.

The second dam DAM2 can include a second insulating layer pattern 1420 disposed on a protruding portion 1410 and a bank pattern 1419 disposed on the second insulating layer pattern 1420. An organic layer 470 and a second electrode 480 of a light emitting element EL can extend and disposed on the bank pattern 1419.

As the first dams DAM1 have the reverse taper structure, the organic layer 470 and the second electrode 480 can be not extended continually or integrally from an area where the second dam DAM2 is disposed. For example, the organic layer 470 and the second electrode 480 can be disposed only on the second insulating layer pattern 1420, and thus, at least one of the organic layer 470 and the second electrode 480 can be disconnected in an area between the second dam DAM2 and an adjacent first dam DAM1 and/or an area between adjacent first dams DAM 1.

By applying this configuration, even when moisture and oxygen penetrate through the third hole H3, since the organic layer 470 and the second electrode 480 of the light emitting element EL are disposed in a disconnected form due to the plurality of first dams DMA1 located adjacent to the third hole H3, the display device can provide the advantage of protecting the light emitting areas (EA1 and EA2) from the penetration of moisture and oxygen.

As described above, the display panel and display device 100 according to the various examples, aspects, and embodiments of the present disclosure have been discussed with reference to the figures.

According to the aspects described herein, a display panel and a display device can be provided that have a structure where first and second open areas are formed in a non-light emitting area between subpixels, and are capable of preventing leakage current from flowing between subpixels by causing portions of an organic layer to be separated from each other.

According to the aspects described herein, a display panel and a display device can be provided that have a structure where one subpixel includes a plurality of light emitting areas and a plurality of non-light emitting areas, and thereby, is capable of being driven with low power through excellent emission efficiency.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention.

What is claimed is:

1. A display panel comprising:
a substrate on which a plurality of subpixels are disposed;
a first insulating layer disposed on the substrate;
a disconnection inducing layer disposed on the first insulating layer and comprising a first open area exposing a portion of an upper surface of the first insulating layer;
a second insulating layer disposed on the substrate and comprising at least one opened portion in at least one subpixel among the plurality of subpixels;
a first electrode disposed on the second insulating layer and overlapping with the at least one opened portion;
a bank disposed on a portion of an upper surface of the first electrode and the second insulating layer, and comprising a respective opening in each of the plurality of subpixels;
an organic layer disposed on the first electrode; and
a second electrode disposed on the organic layer,
wherein the second insulating layer comprises a second open area in an area overlapping with the first open area, and
wherein a portion of the second insulating layer overlaps with a portion of the first open area of the disconnection inducing layer.

2. The display panel of claim 1, wherein a width of the first open area is greater than a width of the second open area.

3. The display panel of claim 1, wherein the second open area overlaps with the portion of the upper surface of the first insulating layer exposed by the first open area.

4. The display panel of claim 1, wherein the organic layer is disposed on the upper surface of the first insulating layer in an area where the first open area and the second open area overlap with each other.

5. The display panel of claim 1, wherein the organic layer is not disposed on the upper surface of the first insulating layer in an area where the first open area and the second open area overlap with each other.

6. The display panel of claim 5, wherein the second electrode is disposed on the upper surface of the first insulating layer in an area where the first open area and the second open area overlap with each other.

7. The display panel of claim 1, wherein the at least one subpixel comprises at least two light emitting areas and at least two non-light emitting areas.

8. The display panel of claim 7, wherein the at least one subpixel comprises a first light emitting area, a first non-light emitting area adjacent to the first light emitting area, a second light emitting area adjacent to the first non-light emitting area, and a second non-light emitting area adjacent to the second light emitting area.

9. The display panel of claim 8, wherein the first light emitting area is an area where the first electrode overlaps with the at least one opened portion, and where the at least one opened portion and the bank do not overlap with each other.

10. The display panel of claim 8, wherein the first non-light emitting area is an area where the bank overlaps with a flat portion of the at least one opened portion.

11. The display panel of claim 8, wherein the second light emitting area corresponds to an area where the first electrode overlaps with an inclined surface of the at least one opened portion.

12. The display panel of claim 8, wherein a luminance level of the second light emitting area is equal to or less than a luminance level of the first light emitting area.

13. The display panel of claim 8, wherein the second non-light emitting area overlaps with the first and second open areas.

14. The display panel of claim 8, wherein the first and second open areas are disposed between respective second light emitting areas of adjacent subpixels among the plurality of subpixels.

15. The display panel of claim 1, wherein the second open area has a structure where a plurality of bar shapes are connected on a plane view, or at least one of the plurality of bar shapes is bent.

16. The display panel of claim 1, wherein the substrate comprises an active area and a non-active area adjacent to the active area, and at least one hole is disposed in the active area of the substrate.

17. The display panel of claim 16, further comprising a plurality of dams disposed on the substrate and disposed adjacent to the at least one hole.

18. The display panel of claim 17, wherein at least one dam among the plurality of dams comprises a protruding portion, a second insulating layer pattern disposed on the protruding portion, an organic layer pattern disposed on the second insulating layer pattern, and a second electrode pattern disposed on the organic layer pattern.

19. The display panel of claim 18, wherein the protruding portion is integrally formed with the disconnection inducting layer.

20. A display device comprising:
a substrate on which a plurality of subpixels are disposed;
a first insulating layer disposed on the substrate;
a disconnection inducing layer disposed on the first insulating layer and comprising a first open area exposing a portion of an upper surface of the first insulating layer; and
a second insulating layer disposed on the substrate and comprising at least one opened portion in at least one subpixel among the plurality of subpixels,
wherein the second insulating layer comprises a second open area in an area overlapping with the first open area, and
wherein a portion of the second insulating layer overlaps with a portion of the first open area of the disconnection inducing layer.
